(19) United States
(12) Patent Application Publication
(10) Pub. No.: US 2024/0329272 A1
(43) Pub. Date: Oct. 3, 2024

(54) METHOD AND SYSTEM FOR MECHANICAL EARTH MODEL PARAMETER ESTIMATION

(71) Applicant: SAUDI ARABIAN OIL COMPANY, Dhahran (SA)

(72) Inventor: Hussain AlBahrani, Qatif (SA)

(73) Assignee: SAUDI ARABIAN OIL COMPANY, Dhahran (SA)

(21) Appl. No.: 18/192,523

(22) Filed: Mar. 29, 2023

(51) Int. Cl. G01V 1/50; G06F 30/23

(52) U.S. Cl. CPC G01V 1/50; G06F 30/23

(57) ABSTRACT

A method for obtaining mechanical earth model (MEM) parameters, the method involving obtaining an ultrasonic image log for a borehole, based on the ultrasonic image log, obtaining an estimate of a borehole geometry for an entire circumference of the borehole in an interval of the ultrasonic image log, and estimating the MEM parameters using the estimate of the borehole geometry.

### BACKGROUND

Mechanical earth models (MEMs) are a crucial component of any well design process. Because MEMs describe the subterranean formation's in-situ stresses and rock mechanical properties, they are the main input into any geomechanics model. This means high impact issues like wellbore instability, drilling induced fractures, and hydraulic fracturing success probability are all directly dependent on the reliability of the provided MEMs. Considering that MEMs have been historically developed based on empirical correlations and expert manual interpretations of logging data, intuitively, their accuracy has a large margin for improvement. Specifically, because the determination of the in-situ maximum horizontal stress is based on manual interpretations of caliper or image logs, the result of this interpretation can vary greatly from one user to the other. Accordingly, a method and a system that interpret image and caliper logs data and produce consistent estimates of different MEM parameters may be desirable.

### SUMMARY

This summary is provided to introduce a selection of concepts that are further described below in the detailed description. This summary is not intended to identify key or essential features of the claimed subject matter, nor is it intended to be used as an aid in limiting the scope of the claimed subject matter.

In general, in one aspect, embodiments relate to a method for obtaining mechanical earth model (MEM) parameters, the method comprising: obtaining an ultrasonic image log for a borehole; based on the ultrasonic image log, obtaining an estimate of a borehole geometry for an entire circumference of the borehole in an interval of the ultrasonic image log; and estimating the MEM parameters using the estimate of the borehole geometry.

In general, in one aspect, embodiments relate to a method for obtaining mechanical earth model (MEM) parameters, the method comprising: obtaining a resistivity image log and a mechanical caliper log for a borehole; based on the resistivity image log, adjusted using values from the mechanical caliper log, obtaining an estimate of a borehole geometry for an entire circumference of the borehole in an interval of the resistivity image log; and estimating the MEM parameters using the estimate of the borehole geometry.

In general, in one aspect, embodiments relate to a system for obtaining mechanical earth model (MEM) parameters, the system comprising: an ultrasound image log interpretation engine executing on at least one processor and configured to: obtain an ultrasonic image log for a borehole; and a mechanical earth model simulation engine executing on the at least one processor and configured to: based on the ultrasonic image log, obtain an estimate of a borehole geometry for an entire circumference of the borehole in an interval of the ultrasonic image log, and estimate the MEM parameters using the estimate of the borehole geometry.

Other aspects and advantages of the claimed subject matter will be apparent from the following description and the appended claims.

### BRIEF DESCRIPTION OF DRAWINGS

Specific embodiments of the disclosed technology will now be described in detail with reference to the accompanying figures. Like elements in the various figures are denoted by like reference numerals for consistency.

FIG. 1 shows a drilling scenario, in accordance with embodiments of the disclosure.

FIG. 2 shows a system for mechanical earth model parameter estimation, in accordance with embodiments of the disclosure.

FIG. 3 shows a flowchart of a method for mechanical earth model parameter estimation, in accordance with embodiments of the disclosure.

FIG. 4A shows a sample ultrasonic image log, in accordance with embodiments of the disclosure.

FIG. 4B1 shows a method for calibrating an ultrasonic image log interpretation algorithm, in accordance with embodiments of the disclosure.

FIG. 4B2 shows an implementation example of a method for calibrating an ultrasonic image log interpretation algorithm, in accordance with embodiments of the disclosure.

FIG. 4C1 shows a method for estimating a borehole geometry based on an ultrasonic image log, in accordance with embodiments of the disclosure.

FIG. 4C2 shows an implementation example of a method for estimating a borehole geometry based on an ultrasonic image log, in accordance with embodiments of the disclosure.

FIG. 4D shows an example of a comparison of an ultrasonic image log and the corresponding RGB numbers, in accordance with embodiments of the disclosure.

FIG. 4E shows an example of an ultrasonic log interpretation, in accordance with embodiments of the disclosure.

FIG. 5A shows a combination of a sample resistivity image log and a corresponding sample mechanical caliper log, in accordance with embodiments of the disclosure.

FIG. 5B1 shows a method for estimating a borehole geometry based on a resistivity image log, in accordance with embodiments of the disclosure.

FIG. 5B2 shows an implementation example of a method for estimating a borehole geometry based on a resistivity image log, in accordance with embodiments of the disclosure.

FIG. 5C shows an example of a resistivity image log and the corresponding RGB numbers, in accordance with embodiments of the disclosure.

FIG. 5D shows an example of a resistivity log interpretation, in accordance with embodiments of the disclosure.

FIG. 6 shows an illustration of an enlarged wellbore, in accordance with embodiments of the disclosure.

FIG. 7A shows an illustration of the use of a stress regime polygon, in accordance with embodiments of the disclosure.

FIG. 7B shows an illustration of a pre-processing for a finite element model (FEM) simulation, in accordance with embodiments of the disclosure.

FIG. 7C shows an example of an FEM simulation, in accordance with embodiments of the disclosure.

FIG. 7D shows example recommendations of muds weights and downhole pressures, in accordance with embodiments of the disclosure.

FIG. 8 shows a computer system in accordance with one or more embodiments.

### DETAILED DESCRIPTION

In the following detailed description of embodiments of the disclosure, numerous specific details are set forth in order to provide a more thorough understanding of the disclosure. However, it will be apparent to one of ordinary skill in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In general, embodiments of the disclosure include systems and methods for mechanical earth model (MEM) parameter estimation. MEMs produced through the proposed algorithms can be incorporated into geomechanics models. These geomechanics models are intended to issue recommendations regarding wellbore instability while drilling or hydraulic fracturing job design. Because of the higher accuracy promised by embodiments of the disclosure, the wellbore instability recommendations may be reliable enough to reduce the drilling non-productive time (NPT) that is known to occur due to inaccurate predictions. Also, due to the automated nature of embodiments of the disclosure, the application of any relevant geomechanics model can be extended to a larger number of fields, wells, and rigs without the need for an expert to generate the manual interpretation. Finally, the application of embodiments of the disclosure in any relevant hydraulic fracturing geomechanics model may lead to more reliable job design, which in-turn may improve the efficiency of these jobs and enhance hydrocarbon production.

A general description of a drilling scenario, followed by a description of method and system for MEM parameter estimation in accordance with embodiments of the disclosure, is subsequently provided.

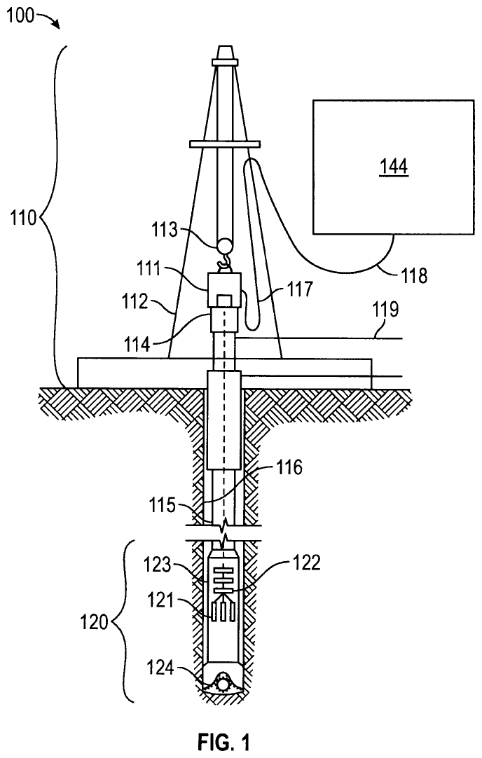

FIG. 1 shows a drilling scenario (100) in accordance with embodiments of the disclosure. The drilling scenario (100) includes a top drive drilling rig (110) arranged around the setup of a drill bit logging tool (120). A top drive drilling rig (110) may include a top drive (111) that may be suspended in a derrick (112) by a travelling block (113). In the center of the top drive (111), a drive shaft (114) may be coupled to a top pipe of a drill string (115), for example, by threads. The top drive (111) may rotate the drive shaft (114), so that the drill string (115) and a drill bit logging tool (120) cut the rock at the bottom of a wellbore (116). A power cable (117) supplying electric power to the top drive (111) may be protected inside one or more service loops (118) coupled to a control system (144). Drilling mud may be pumped into the wellbore (116) through a mud line (119), the drive shaft (114), and/or the drill string (115).

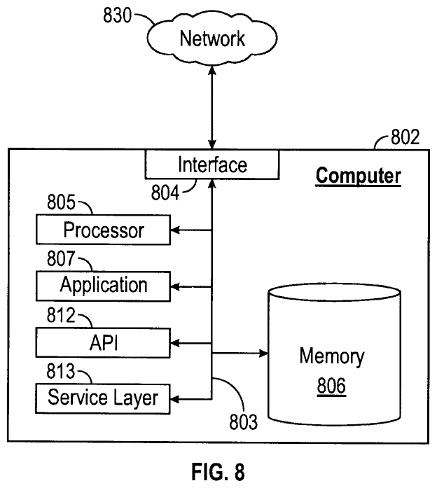

The control system (144) may include one or more programmable logic controllers (PLCs) that include hardware and/or software with functionality to control one or more processes performed by the drilling system (100). Specifically, a programmable logic controller may control valve states, fluid levels, pipe pressures, warning alarms, and/or pressure releases throughout a drilling rig. In particular, a programmable logic controller may be a ruggedized computer system with functionality to withstand vibrations, extreme temperatures, wet conditions, and/or dusty conditions, for example, around a drilling rig. For example, the control system (144) may be coupled to the sensor assembly (123) in order to perform various program functions for up-down steering and left-right steering of the drill bit (124) through the wellbore (116). While one control system is shown in FIG. 1, the drilling system (100) may include multiple control systems for managing various well drilling operations, maintenance operations, well completion operations, and/or well intervention operations. The control system (144) may be based on a computer system as shown FIG. 8.

The wellbore (116) may include a bored hole that extends from the surface into a target zone of the hydrocarbon-bearing formation, such as the reservoir. An upper end of the wellbore (116), terminating at or near the surface, may be referred to as the “up-hole” end of the wellbore (116), and a lower end of the wellbore, terminating in the hydrocarbon-bearing formation, may be referred to as the “downhole” end of the wellbore (116). The wellbore (116) may facilitate the circulation of drilling fluids during well drilling operations, the flow of hydrocarbon production (“production”) (e.g., oil and gas) from the reservoir to the surface during production operations, the injection of substances (e.g., water) into the hydrocarbon-bearing formation or the reservoir during injection operations, or the communication of monitoring devices (e.g., logging tools) into the hydrocarbon-bearing formation or the reservoir during monitoring operations (e.g., during in situ logging operations).

As further shown in FIG. 1, sensors (121) may be included in the sensor assembly (123), which is positioned adjacent to a drill bit (124) and coupled to the drill string (115). Sensors (121) may also be coupled to a processor assembly (123) that includes a processor, memory, and an analog-to-digital converter (122) for processing sensor measurements. The sensors (121) may include acoustic sensors, such as ultrasonic imaging sensors. The sensors (121) may also include transmitters and receivers to measure resistivity. The sensors (121) may include hardware and/or software for generating different types of well logs (e.g., ultrasonic image logs and resistivity image logs) that may provide well data about a wellbore, including porosity of wellbore sections, gas saturation, bed boundaries in a geologic formation, fractures in the wellbore or completion cement, and/or many other pieces of information about a formation. If such well data is acquired during well drilling operations (i.e., logging-while-drilling (LWD)), then the information may be used to make adjustments to drilling operations in real-time. Such adjustments may include rate of penetration (ROP), drilling direction, altering mud weight, and many others drilling parameters.

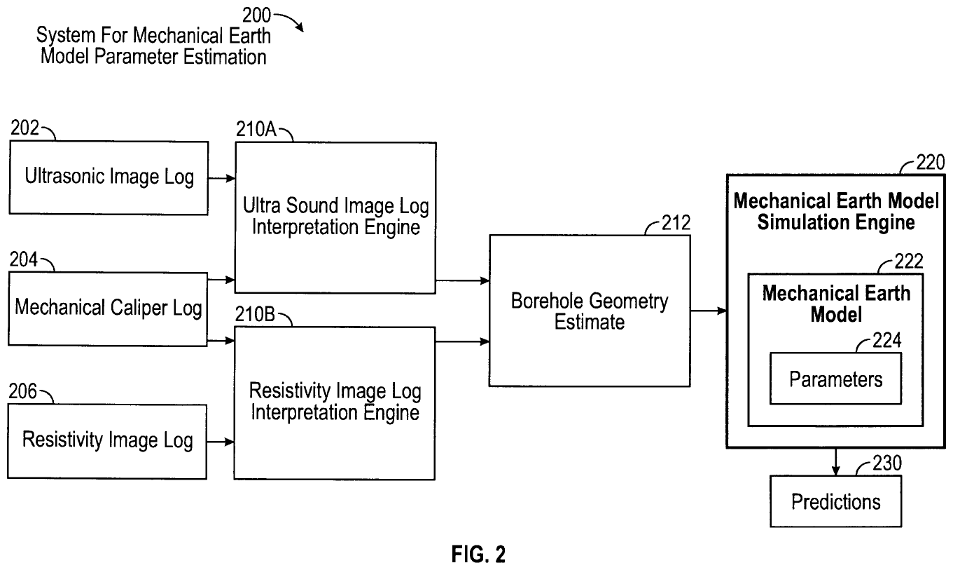

One or more components of the drilling system (100) may form a system for MEM parameter estimation, in accordance with embodiments of the disclosure. An example of a system for MEM parameter estimation is described below in reference to FIG. 2. The system for MEM parameter estimation, in accordance with embodiments of the disclosure may include a computing system such as the computing system shown in FIG. 8. The computing system may be the control system (144) or any other computing system.

While FIG. 1 shows various configurations of components, other configurations may be used without departing from the scope of the disclosure. For example, various components in FIG. 1 may be combined to create a single component. As another example, the functionality performed by a single component may be performed by two or more components.

FIG. 2 shows a system (200) for mechanical earth model (MEM) parameter estimation, in accordance with embodiments of the disclosure. The system (200) may rely on various inputs, including, for example, an ultrasonic image log (202), a mechanical caliper log (204), and/or a resistivity image log (206). Detailed descriptions and examples of the ultrasonic image log (202), the mechanical caliper log (204), and the resistivity image log (206), including their acquisition, are provided below.

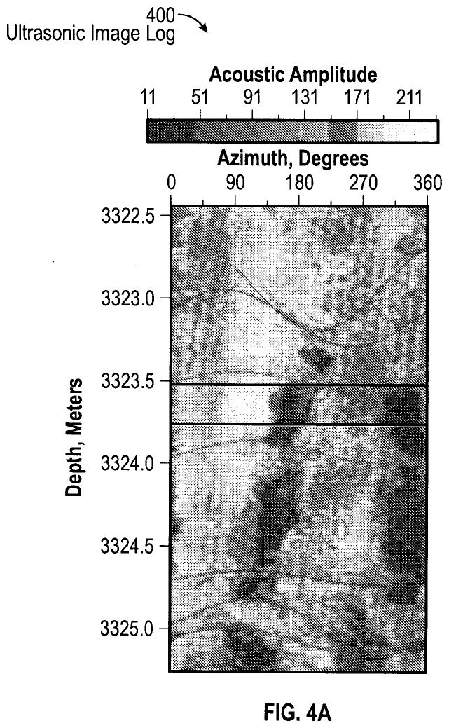

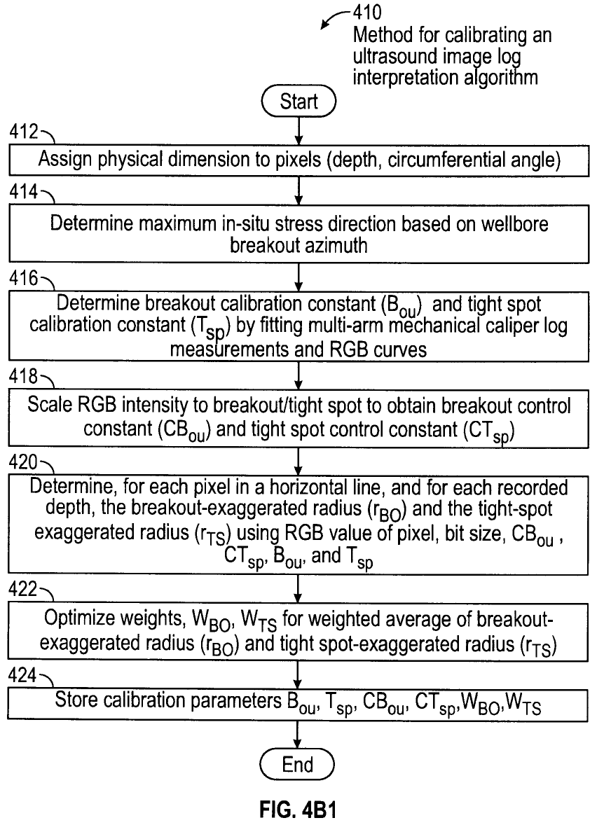

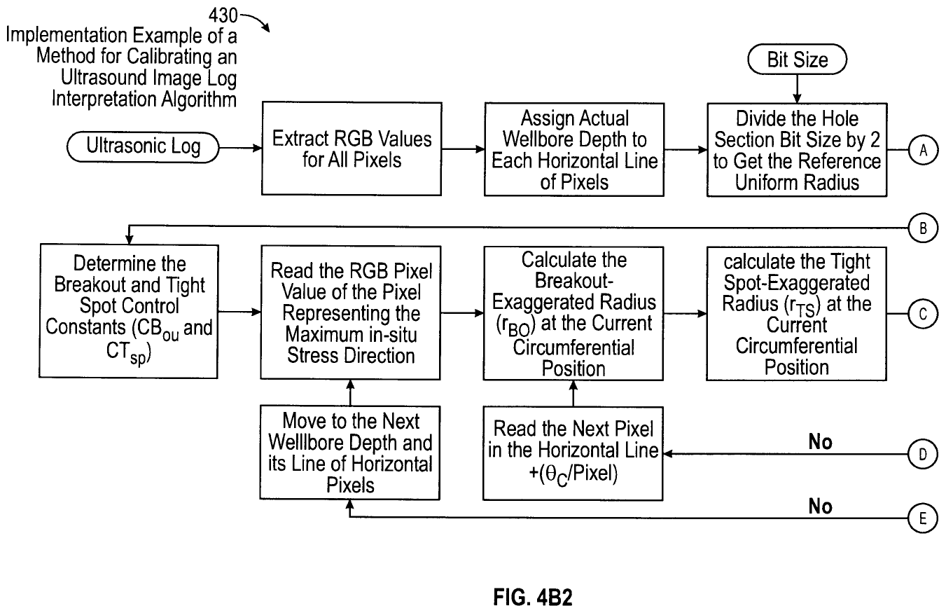

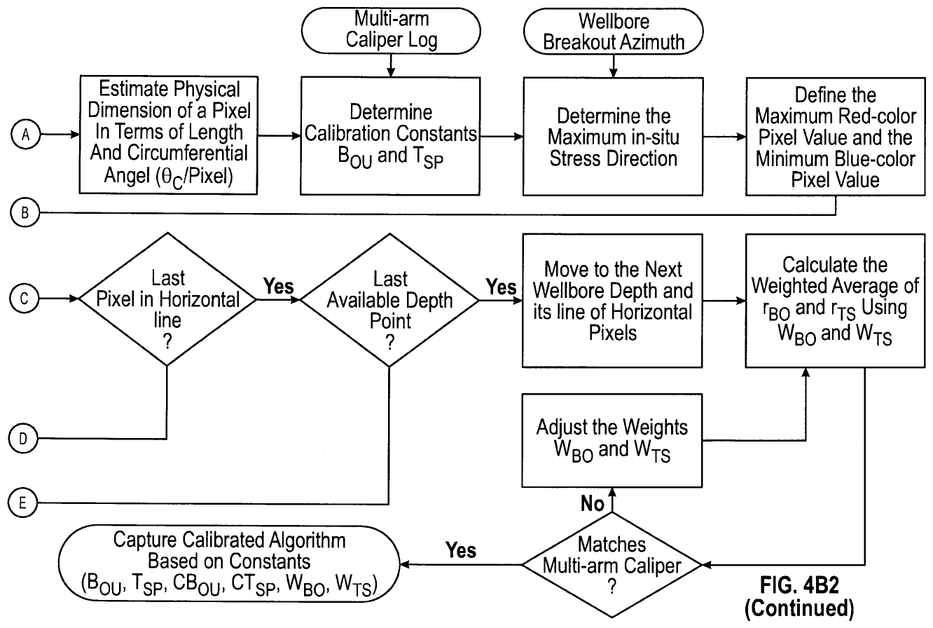

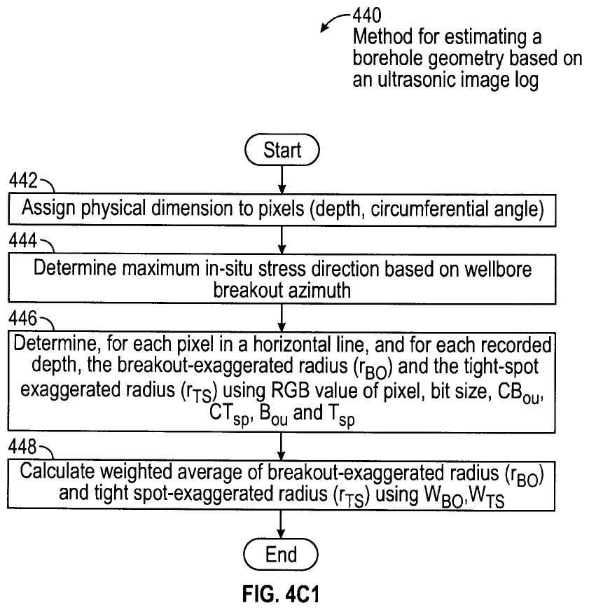

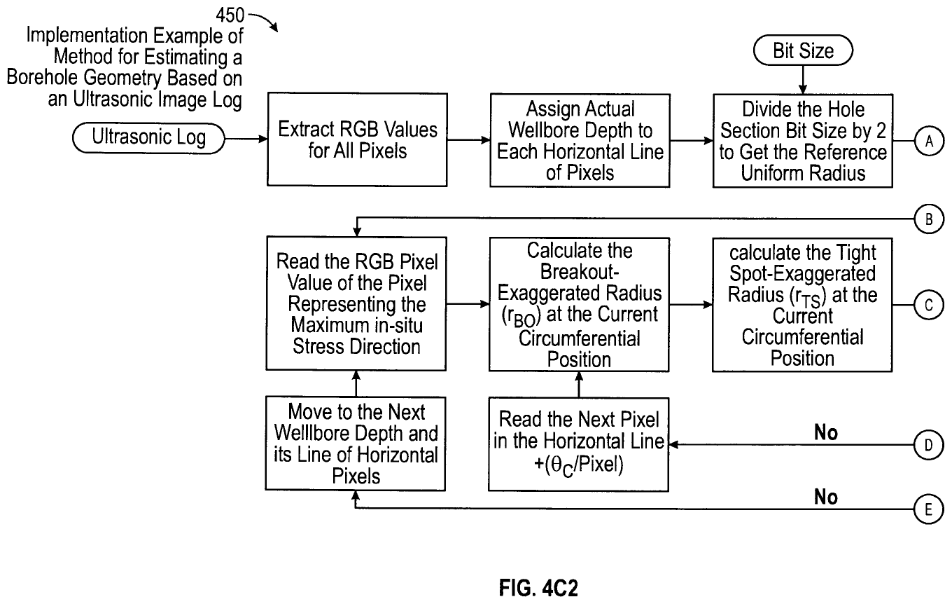

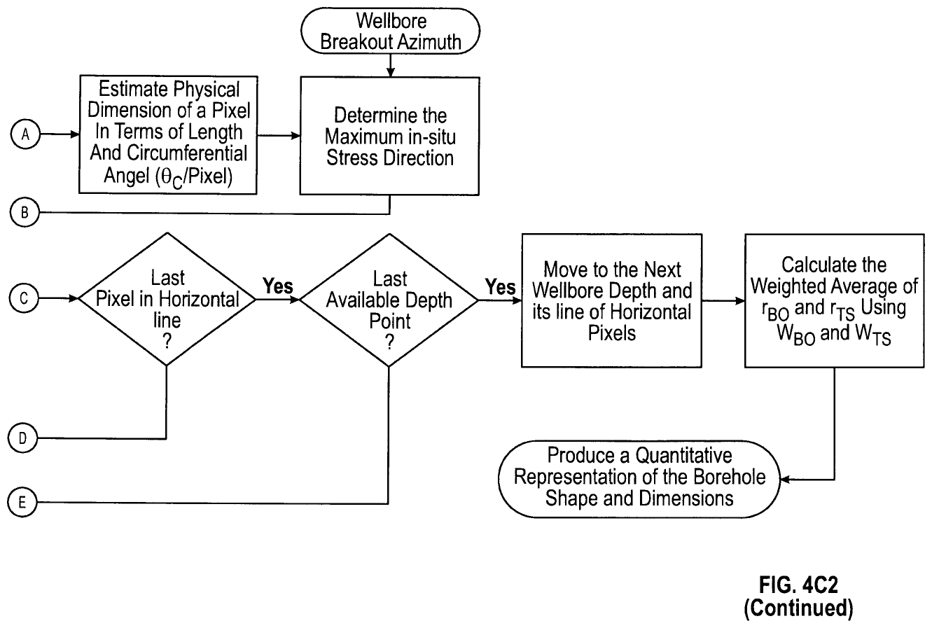

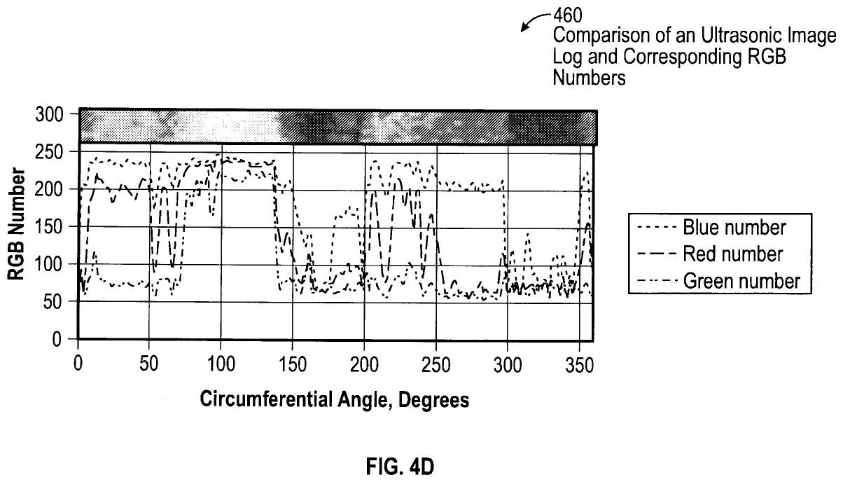

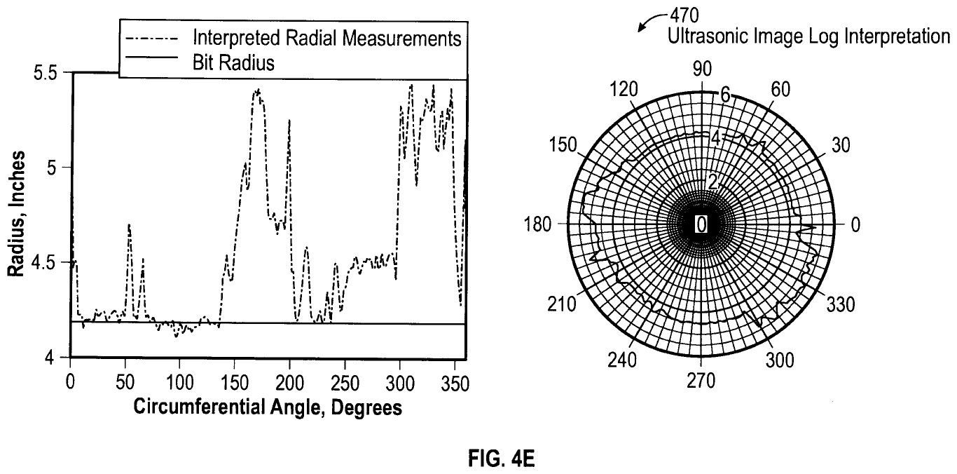

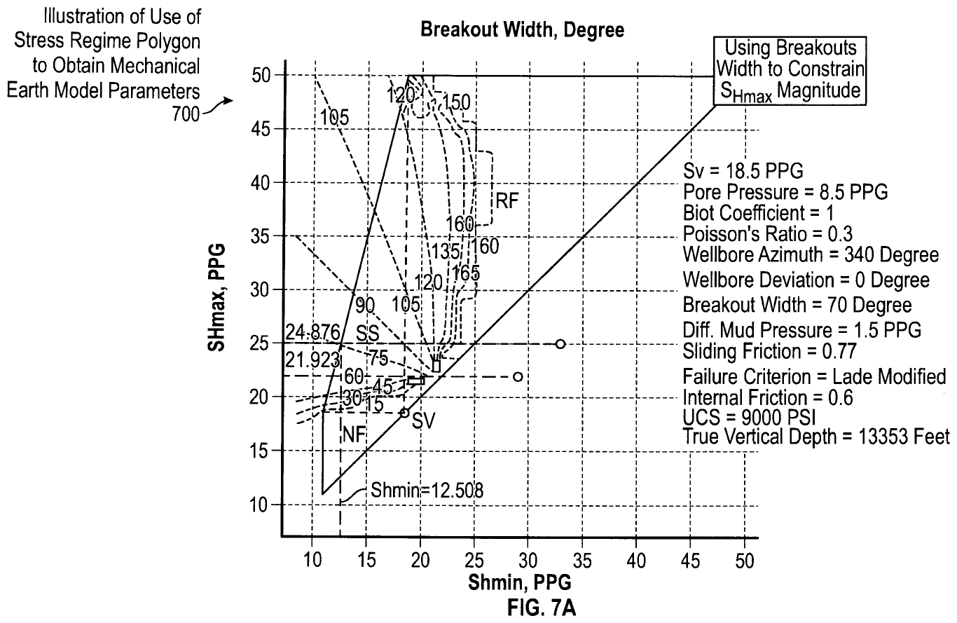

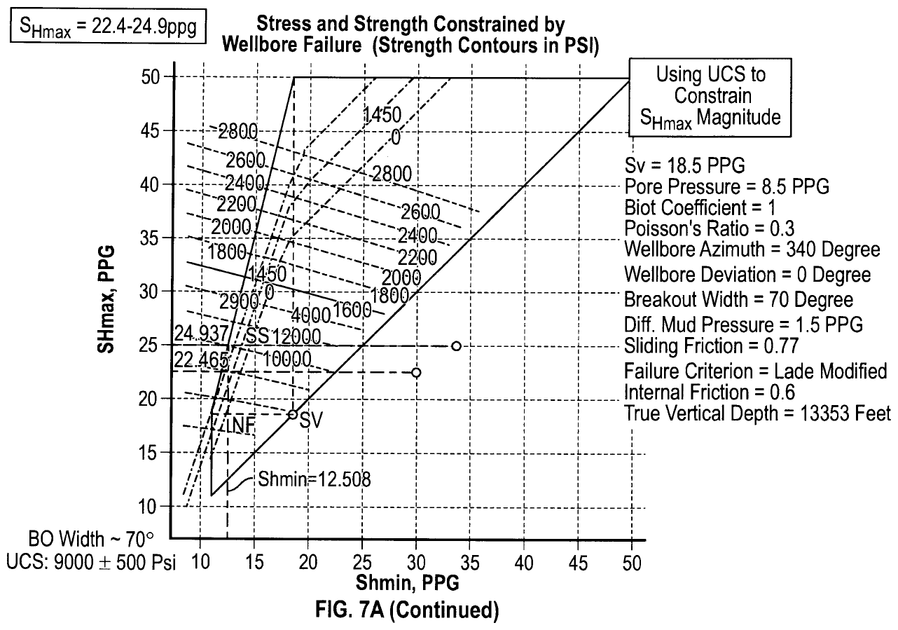

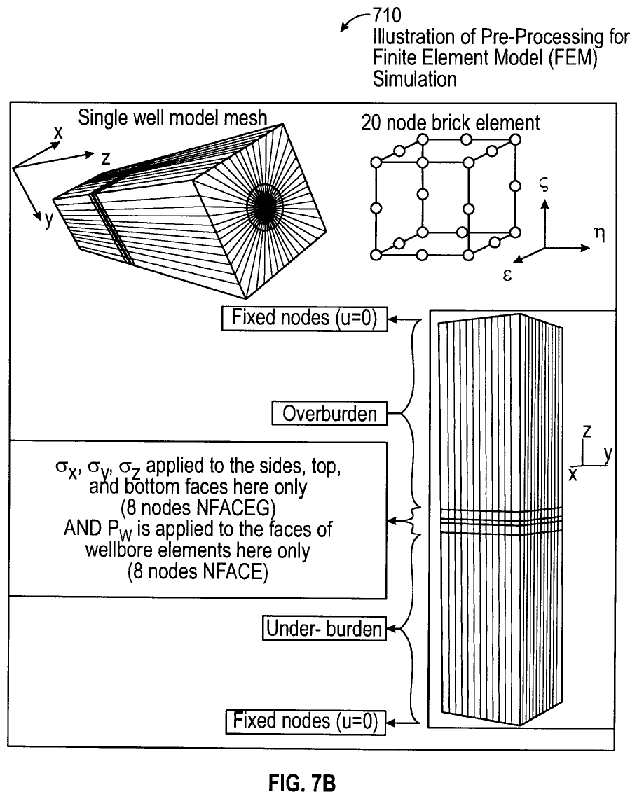

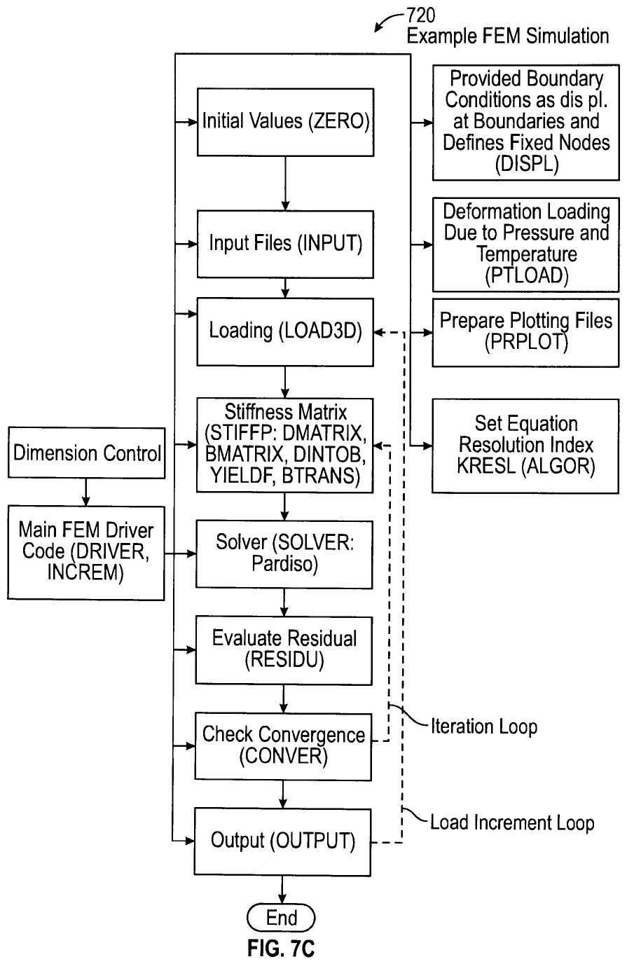

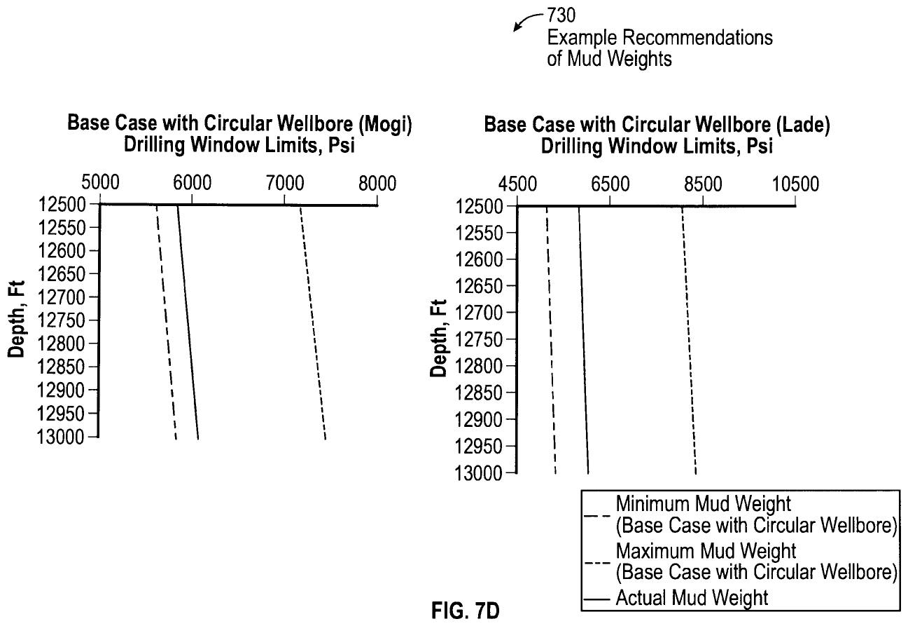

An ultrasound image log interpretation engine (210A), in one or more embodiments, generates a borehole geometry estimate (212) from the ultrasonic image log (202). A calibration may be performed using the mechanical caliper log (204), prior to performing the estimation. Alternatively, a resistivity image log interpretation engine (210B) may generate the borehole geometry estimate (212) from the resistivity image log (206) and the mechanical caliper log (204). A detailed description of the operations performed by the ultrasound image log interpretation engine (210A) and the resistivity image log interpretation engine (210B) is provided below, e.g., with reference to FIGS. 4B1, 4B2, 4C1, 4C2, 5B1, and 5B2. The ultrasound image log interpretation engine (210A) and the resistivity image log interpretation engine (210B) may be implemented on a computing device, e.g., as shown in FIG. 8. Based on the borehole geometry estimate (212), parameters (224) of a mechanical earth model (222) may be estimated by a mechanical earth model simulation engine (220). Parameters (224) of the MEM estimated may include, for example, the in-situ maximum horizontal stress and the in-situ minimum horizontal stress, the pore pressure and the linear elastic rock mechanical properties (Young's modulus and Poisson's ratio), etc. The operations performed by the mechanical earth model simulation engine (220) may be similar to those conventionally performed, although using the borehole geometry estimate as obtained in accordance with embodiments of the disclosure. The mechanical earth model simulation engine (220) may be implemented on a computing system, e.g., as shown in FIG. 8. The parameterized mechanical earth model (222) may be used to make predictions (230), e.g., as illustrated in FIGS. 7A-7D.

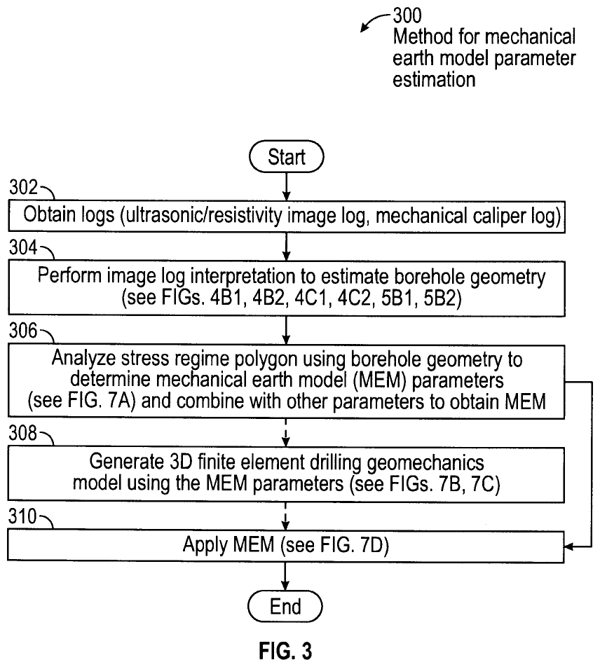

FIGS. 3, 4B1, 4B2, 4C1, 4C2, 5B1, and 5B2 show flowcharts in accordance with one or more embodiments. FIG. 3 shows a method for mechanical earth model (MEM) parameter estimation, in accordance with embodiments of the disclosure, whereas FIGS. 4B1, 4B2, 4C1, 4C2, 5B1, and 5B2 show additional methods that may be executed as part of the method of FIG. 3.

Execution of one or more steps in FIGS. 3, 4B1, 4B2, 4C1, 4C2, 5B1, and 5B2 may involve one or more components of the system as described in FIG. 2. While the various steps in FIGS. 3, 4B1, 4B2, 4C1, 4C2, 5B1, and 5B2 are presented and described sequentially, one of ordinary skill in the art will appreciate that some or all of the steps may be executed in different orders, may be combined or omitted, and some or all of the steps may be executed in parallel. Furthermore, the steps may be performed actively or passively.

Turning to FIG. 3, the method (300), in one or more embodiments utilizes either resistivity or ultrasonic based image logs along with wireline caliper measurements to first quantify areas of enlargements or washouts within a wellbore section. These data are then used to estimate the parameters of the MEM model.

The MEM may then be used to plan and execute, for example, drilling operations. As a borehole is drilled, hydraulic pressure of the drilling mud must replace the support lost by removal of the original column of rock. However, mud pressure being uniform in all directions cannot exactly balance the earth stress. Consequently, rock surrounding the borehole is distorted or strained, and may fail if the redistributed stresses exceed rock strength. The bottom line for the drilling engineer striving to maintain stable hole is choosing the right mud weight. This may be facilitated by using MEMs to evaluate wellbore stability and to choose optimum mud weight.

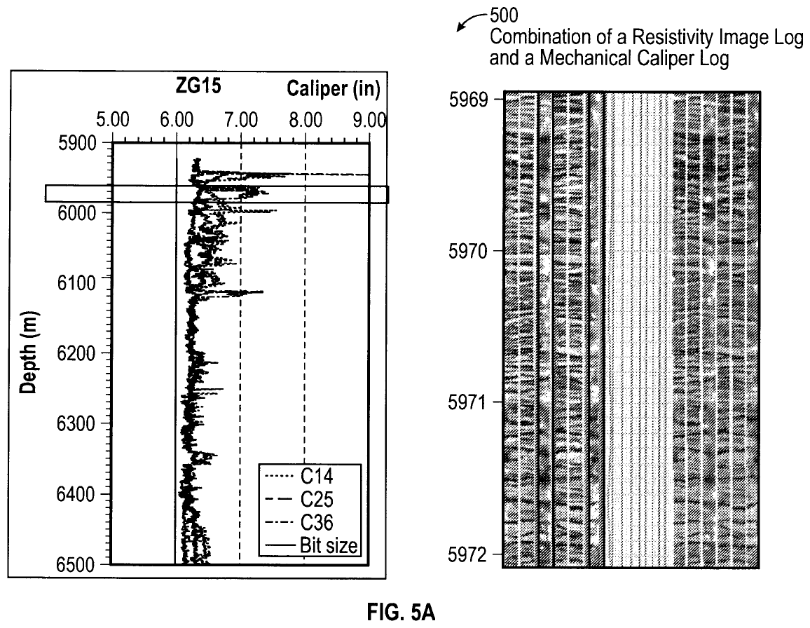

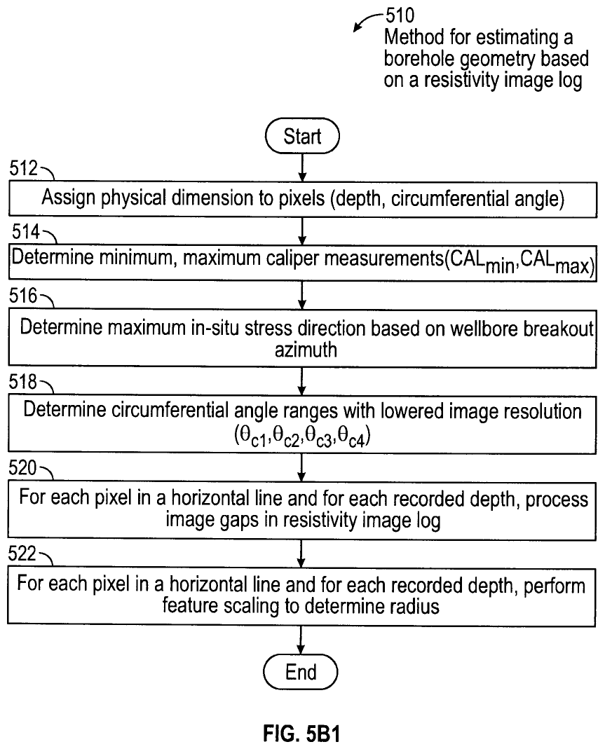

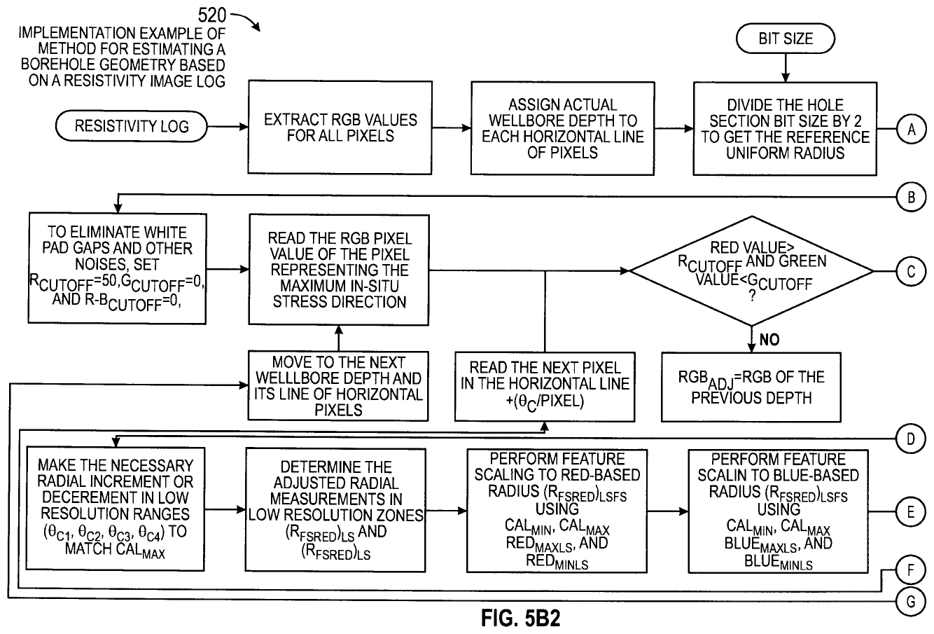

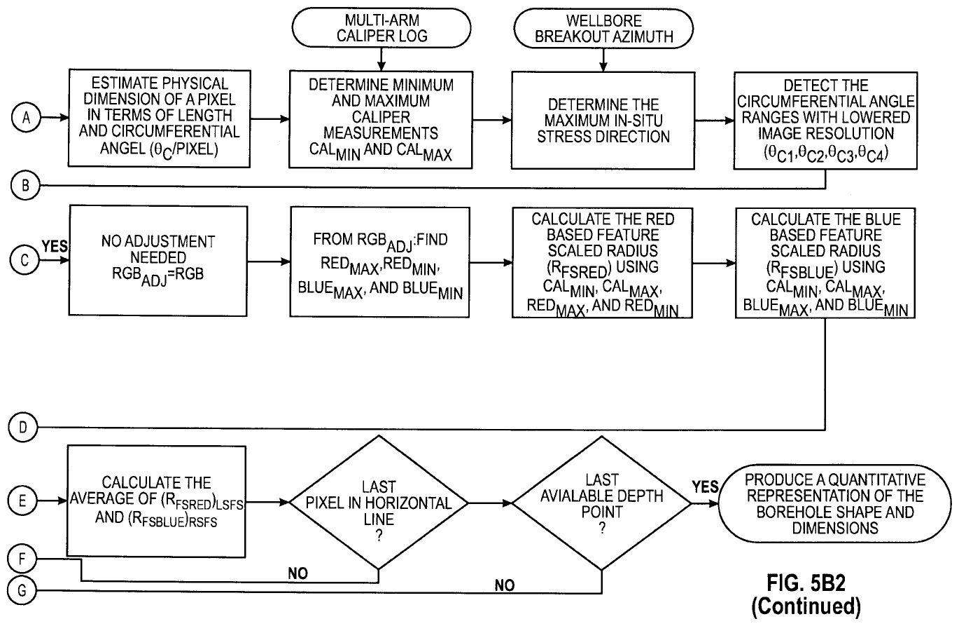

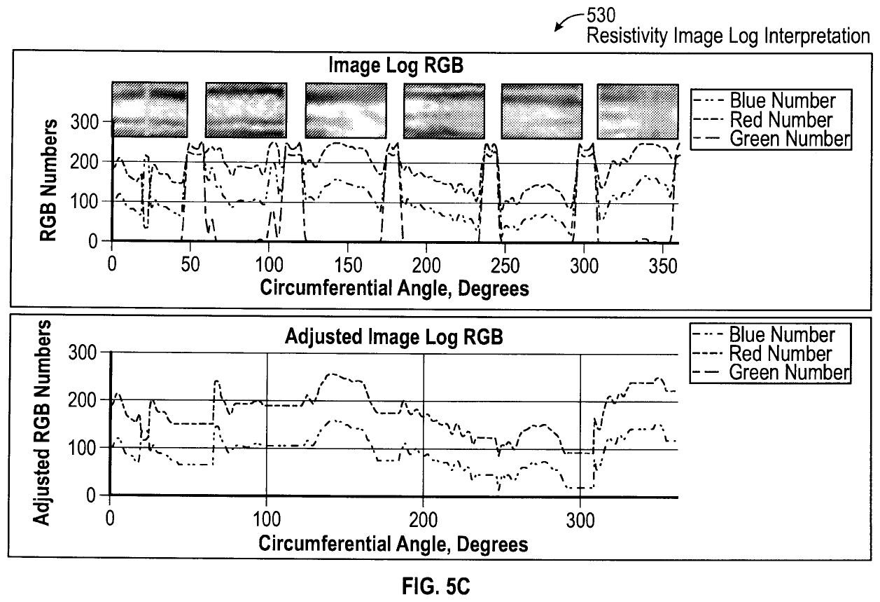

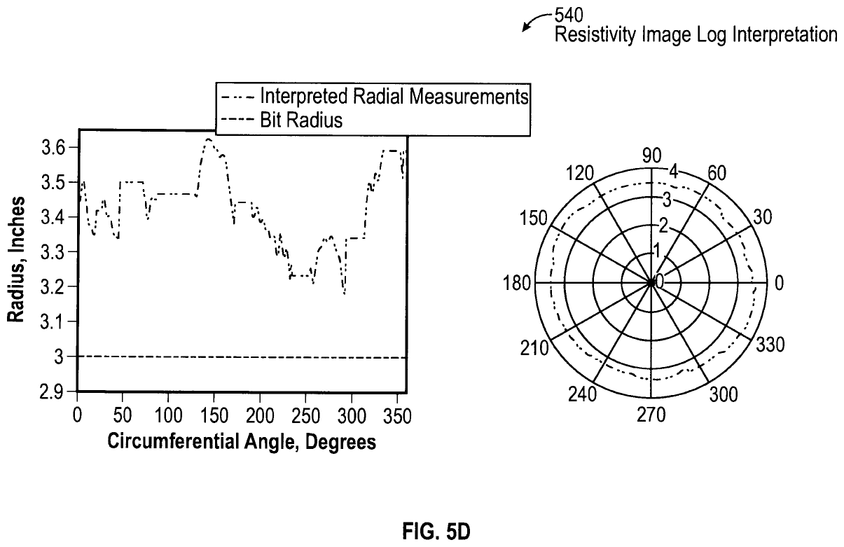

In Step 302, logs are obtained. The logs may include an ultrasonic image log as described in reference to FIGS. 4A-4C2 and/or a resistivity image log as described in reference to FIGS. 5A-5B2. In addition, a caliper log may be obtained. A detailed description is provided below in reference to FIGS. 4A-4C2 and 5A-5B2.

In Step 304, an image log interpretation is performed to obtain an estimate of a borehole geometry. A detailed description of the steps performed using an ultrasonic image log is provided below in reference to FIGS. 4B1, 4B2, 4C1 and 4C2. A detailed description of the steps performed using a resistivity image log is provided below in reference to FIGS. 5B1 and 5B2. Briefly summarized, the method reads the Red-Green-Blue (RGB) values of each pixel in the image log and then assigns a radial measurement to that reading. The generated radial measurements are calibrated using the caliper log data. The end result of this process is radial measurements that describe the wellbore dimensions across the 360° range. These radial measurements are then filtered for enlargements by comparing them to the size of the drill bit that was used to drill the hole section being analyzed.

Step 306, the borehole geometry is used to perform a stress regime polygon analysis. MEM parameters such as the in-situ maximum horizontal stress and the in-situ minimum horizontal stress may be obtained. A detailed description is provided in reference to FIG. 7A. Additional MEM parameters (e.g., obtained Young's modulus and Poisson's ratio) may be obtained using conventional methods such as wireline acoustic logs, lab-based core sample measurements, etc.

In Step 308, a 3D finite element drilling geomechanics model is generated for the MEM parameters using the inverse problem. A detailed description is provided in reference to FIGS. 7B and 7C.

In Step 310, the MEM is applied to plan and/or conduct operations such as drilling. For example, various drilling parameters (e.g., mud weight, drilling direction, etc.) may be selected such that wellbore instabilities while drilling are avoided. In addition, during production, conditions such as sand production, perforation stability, etc., may be predicted. Similarly, the MEM may be used to plan a hydraulic fracturing operation. A description is provided in reference to FIG. 7D. Step 310 may further involve using the 3D finite element drilling geomechanics model, obtained in Step 308. Unlike conventional geomechanics models, the model obtained in Step 308 considers plastic behavior of rock and may be used in real-time, e.g., in a while-drilling application.

Turning to FIGS. 4A-4E an ultrasonic image logging-based approach to estimating a borehole geometry is described.

FIG. 4A shows a sample ultrasonic image log, in accordance with embodiments of the disclosure. The sample ultrasonic image log (400) is from an 8.375″ wellbore and shows stress-induced wellbore enlargements. The zone identified by a black rectangle is the interval used for providing an example of image log interpretation, in the following discussion.

FIGS. 4B1, 4B2, 4C1, and 4C2 show methods that enable estimation of a borehole geometry based on an ultrasound image log. While FIGS. 4C1 and 4C2 show methods to perform the estimation, FIGS. 4B1 and 4B2 show methods for calibrating the underlying algorithm, needed to perform the prediction. The next paragraphs provide a general description of the methodology, followed by a more detailed description of the methods shown in FIGS. 4B1, 4B2, 4C1 and 4C2.

The methods of FIGS. 4B1, 4B2, 4C1, and 4C2 are designed to convert a specific type of image log, in this case an ultrasonic-based image log, into caliper readings that cover the 360° of the wellbore circumference. Accordingly, instead of relying on conventional mechanical caliper logs which typically provide radial measurements at only four circumferential angles (0°, 90°, 180°, 270°), embodiments of the disclosure may provide radial measurements at all circumferential angles. As is the case with CT-scans, the resolution of radial measurements is dependent on the image log resolution.

Ultrasonic image logs may be particularly suitable for the method as described. This may be for at least two main reasons. First, unlike resistivity-based image logs, ultrasonic images have no image Ts, and therefore, may provide a full and comprehensive description of the wellbore state. Second, they are available in logging while drilling (LWD) tools in the form of density-based images, which means that they can be used in a real-time setting or a while-drilling setting to feed new information into numerical models.

A significant difference in the interpretation process between lab-based images (CT-scans) and field-based image logs is that field-based image logs cannot be solely relied on to produce an interpretation. This is mainly due to the challenging environment in which these images are taken. This is also due to variations in image attributes between different commercial logging tools. Accordingly, field image logs may require more support information and validation than lab-based images. The support information used for the method as described includes mechanical caliper log readings. More specifically, for each image logging tool, the analysis of its images may be calibrated and validated against mechanical caliper measurements taken from the same interval where the images were produced. This ensures that the quantitative assessment of enlargements and tight spots from an image is validated using the mechanical caliper measurements of the same enlargements and tight spots. Once this calibration has been performed, the calibrated algorithm may be used to interpret images from the same logging tool with more confidence and without the need to run a mechanical caliper log every time an image log is produced.

Turning to FIG. 4B1, a method (410) for calibrating an ultrasonic image log interpretation algorithm is shown. By performing the calibration, the ultrasonic image log interpretation algorithm is enabled to predict a borehole geometry based on an ultrasonic image log that is or has been obtained using a particular image logging tool The calibrated ultrasound image log interpretation algorithm may subsequently be used for the execution of the method of FIG. 4C1.

The method (410) as shown in FIG. 4B1, is based on an algorithm that relies on some data other than the image log itself to perform the calibration process. These data include the bit size, multi-arm mechanical caliper log measurements, and a definition of the direction of the maximum in-situ stress. Accordingly, the inputs to the algorithm are the ultrasonic log as previously discussed, the bit size, a multi-arm mechanical caliper log, and a wellbore breakout azimuth.

Calibration identifies various parameters to be used by the methods of FIGS. 4C1 and 4C2. More specifically, the calibration identifies a set of parameters that enable conversion of RGB color values to radial measurements. The calibration is accomplished by establishing a mapping between an ultrasonic image log and a multi-arm mechanical caliper log, both performed for the same borehole segment.

The calibration relies on bit size, multi-arm mechanical caliper log measurements, and a definition of the direction of the maximum in-situ stress. Using these data, a mapping is established from caliper log measurements to the corresponding ultrasonic image log. Based on this mapping, the RGB color values may then be used to estimate the wellbore geometry, including tight spots, breakouts, etc.

Referring to the flowchart of FIG. 4B1, in Step 412, a physical dimension is assigned to the pixels of the ultrasonic image log. The physical dimensions may include a depth and a circumferential angle. The bit size, e.g., the radius of the drill bit, may be used to determine the circumferential angle.

In Step 414, the maximum in-situ stress direction is determined using the wellbore breakout azimuth (indicating the direction of the minimum in-situ stress), obtained from the ultrasonic image log. The maximum in-situ stress direction is employed to correlate with the direction of wellbore enlargements or breakouts as observed in the ultrasonic image log.

In Step 416, the breakout calibration constant (Bₒᵤ) and tight spot calibration constant (Tₛₚ) are determined by fitting multi-arm mechanical caliper log measurements and RGB curves. The mechanical caliper log may be available for any number of arms, i.e., the log may include more than four measurements. For example, the mechanical caliper log may include 50 or more measurements. In Step 416, the multi-arm mechanical caliper log measurements are used to ascertain the extent of the radial depth of a darkly-colored breakout zone such as the ones shown in FIG. 4A. The multi-arm mechanical caliper log measurements are also used to ensure correct interpretation of tight spots, which are characterized by bright spots on the log and a radius that is smaller than that of the bit size.

Bₒᵤ is a fitting constant determined using an iteration procedure that is repeated until the maximum peaks of the RGB curves match with those of the caliper log curves.

Tₛₚ is a fitting constant determined using an iteration procedure that is repeated until the minimum peaks of the RGB curves match with those of the caliper log curves.

In Step 418, the RGB intensity is scaled to the breakout/tight spot to obtain a breakout control constant (CBₒᵤ) and a tight spot control constant (CTₛₚ), respectively. More specifically, the maximum red color pixel value and the minimum blue color pixel value are extracted, and these two values are used to determine the breakout and tight spot control constants (CBₒᵤ and CTₛₚ) as follows:

$$\\ {CB}_{ou} = \frac{Bit size}{Maximum red color pixel value}$$

$$\\ {CT}_{sp} = \frac{Bit size}{Minimum blue color pixel value}$$

Based on the operations of Step 418, CBₒᵤ and CTₛₚ are correlated to the identification of the most darkly colored region in the image (which represents the deepest breakout) and the most brightly colored region (which represents the tightest spot in the hole).

In Step 420, for each pixel in a horizontal line, and for each recorded depth, the breakout-exaggerated radius (r_{BO}) and the tight-spot exaggerated radius (r_{TS}) are determined using RGB value of pixel, bit size, CBₒᵤ, CTₛₚ, Bₒᵤ, and Tₛₚ. The following calculations may be performed:

$$\\ {r}_{BO} = {B}_{ou} ( Bit size - ( {Red}_{i} \times {CB}_{ou} ) ) + Bit size$$

$$\\ {r}_{TS} = {T}_{sp} ( Bit size - ( {Blue}_{i} \times {CT}_{sp} ) ) + Bit size$$

where Redᵢ and Blueᵢ are the red and blue values for all pixels in a single horizontal line which defines the borehole full circumference. The calculations may be performed in a loop to obtain values for all pixels in a horizontal line, for all recorded depths.

In Step 422, a set of weights, W_{BO}, W_{TS}, is optimized for a weighted average of a breakout-exaggerated radius (r_{BO}) and a tight spot-exaggerated radius (r_{TS}). The optimization is performed based on the following equation:

$$\\ Radius = {W}_{BO} \times {r}_{BO} + {W}_{TS} \times {r}_{TS}$$

where W_{BO} and W_{TS} are the average weights, which are determined through optimization that involves matching the weighted average with the actual multi-arm mechanical caliper log measurements.

In Step 424, the calibration parameters, Bₒᵤ, Tₛₚ, CBₒᵤ, CTₛₚ, W_{BO}, W_{TS}, are stored for application to a particular imaging tool in new hole sections or new wells, to produce full 360° radial measurements, as described below.

As previously noted, the described calibration algorithm needs to be applied to each unique image logging tool to ensure that the images produced from the tool are correctly interpreted. In other words, when using a different too, the calibration may need to be repeated. Also, the calibration may potentially need to be repeated for a calibrated tool when it is run in a new environment.

FIG. 4B2 shows an implementation example of a method for calibrating an ultrasonic image log interpretation algorithm, in accordance with embodiments of the disclosure. In the implementation example (430), individual operations, corresponding to the steps of the method (420), are shown. Other implementations may be used, without departing from the disclosure.

FIG. 4C1 shows a method (440) for estimating a borehole geometry based on an ultrasonic image log, in accordance with embodiments of the disclosure. After the calibration, a newly obtained ultrasonic image log, e.g., of a new hole section or a new well, may be interpreted to produce a full 360° borehole geometry, using the method (440). The method as shown is used for interpreting ultrasonic image logs by converting the RGB color number or values of each pixel of an ultrasonic image log to radial measurements of a borehole. An example of a conversion of the ultrasonic image log into a borehole geometry using the method (440) is shown in Error! Reference source not found.s. 4D and 4E.

Referring to the flowchart of FIG. 4C1, in Step 442, a physical dimension is assigned to the pixels of the ultrasonic image log. The physical dimensions may include a depth and a circumferential angle. The bit size, e.g., the radius of the drill bit, may be used to determine the circumferential angle. In one embodiment, the bit size is identical to the bit size used for the calibration. Accordingly, the operations performed in Step 442 may be similar to the operations performed in Step 412. However, the image log used in Step 442 may be from a different depth and/or a different borehole.

In Step 444, the maximum in-situ stress direction is determined using the wellbore breakout azimuth (indicating the direction of the minimum in-situ stress), obtained from the ultrasonic image log. The maximum in-situ stress direction is employed to correlate with the direction of wellbore enlargements or breakouts as observed in the ultrasonic image log.

In Step 446, for each pixel in a horizontal line, and for each recorded depth, the breakout-exaggerated radius (r_{BO}) and the tight-spot exaggerated radius (r_{TS}) are determined using RGB value of pixel, bit size, CBₒᵤ, CTₛₚ, Bₒᵤ, and Tₛₚ. The following calculations may be performed using the previously introduced equation:

$$\\ {r}_{BO} = {B}_{ou} ( Bit size - ( {Red}_{i} \times {CB}_{ou} ) ) + Bit size$$

$$\\ {r}_{TS} = {T}_{sp} ( Bit size - ( {Blue}_{i} \times {CT}_{sp} ) ) + Bit size$$

where Redᵢ and Blueᵢ are the red and blue values for all pixels in a single horizontal line which defines the borehole full circumference. The calculations may be performed in a loop to obtain values for all pixels in a horizontal line, for all recorded depths.

In Step 448, the weighted average of the breakout-exaggerated radius (r_{BO}) and the tight spot-exaggerated radius (r_{TS}) is calculated using the set of weights, W_{BO}, W_{TS}. The calculation is performed using the previously introduced equation:

$$\\ Radius = {W}_{BO} \times {r}_{BO} + {W}_{TS} \times {r}_{TS}$$

where W_{BO} and W_{TS} are the average weights, which were previously determined during calibration.

FIG. 4C2 shows an implementation example of a method for estimating a borehole geometry based on an ultrasonic image log, in accordance with embodiments of the disclosure. In the implementation example (450), individual operations, corresponding to the steps of the method (440), are shown. Other implementations may be used, without departing from the disclosure.

FIG. 4D shows an example of a comparison (460) of an ultrasonic image log and the corresponding RGB numbers. The plot of the RGB numbers from the ultrasonic image log shows a clear correlation between the locations of enlargements and tight spots in the image and the trends in the RGB numbers. As previously discussed, this correlation may be used along with previously obtained calibration parameters to estimate the radial measurements of the wellbore at all directions. The number of radial measurements that can be produced is dependent on the number of pixels available in the image log (i.e., image resolution). In the example (460), the image log has resolution of 221 pixels per the 360° of the wellbore, which equates to approximately one radius measurement for each 1.63° degrees around the circumference of the wellbore.

FIG. 4E shows an example of an ultrasonic log interpretation (470), in accordance with embodiments of the disclosure. The left panel shows the results of the ultrasonic image log interpretation including radial measurements in cartesian coordinates. The right panel shows the results of the ultrasonic image log interpretation with radial measurements in polar coordinates to reflect the actual shape of the wellbore cross-section. When comparing the ultrasonic image log interval in Error! Reference source not found. 4A to the interpreted radial measurements in Error! Reference source not found. 4E, it can be clearly seen that the dark regions in the image that signify the presence of wellbore enlargements are also reflected as radial measurements that are higher than the bit radius. With ultrasonic images having no image gaps, the entire circumference of the borehole is represented, and therefore, may provide a full and comprehensive description of the wellbore state.

Turning to FIGS. 5A-5D, a resistivity image logging-based approach to estimating a borehole geometry is described.

Similar to the previously described ultrasonic log algorithm, the resistivity image logging-based approach relies on some data other than the image log itself to perform the interpretations process. These data include the bit size, multi-arm mechanical caliper log measurements, and a definition of the direction of the maximum in-situ stress.

FIG. 5A shows a combination of a sample resistivity image log, along with a corresponding mechanical caliper log (500) in accordance with embodiments of the disclosure. The resistivity image log (also known as formation micro-imager log (FMI)) is shown in the right panel of FIG. 5A, and the mechanical multi-arm caliper log is shown in the left panel of FIG. 5A. The regions identified by the two rectangles in the image log to the right are the low-resolution areas. The area identified by a rectangle in the mechanical caliper log to the left is the interval from which the image log to the right was taken. It is used for providing an example of resistive image log interpretation, in the following discussion.

Analogous to the ultrasonic image logging-based approach, the goal of the resistivity image logging-based approach is to convert an image log into caliper readings that cover the 360° of the wellbore.

One significant difference between sonic-based images and resistivity-based images is that resistivity images normally contain several image gaps due to the space between the electrical pads of the resistivity image logging tool. Further, resistivity-based image logs also differ from sonic-based images in the way a breakout (or wellbore enlargement) can be identified. In sonic images, changes in color are sufficient, however, in resistivity images, changes in color alone can be misleading as they can signify laminations, faults, natural, and/or induced fractures along with breakouts. This means that resistivity logs are efficient indicators of physical features within the wellbore, but they may be poor indicators of the spatial (specifically, radial) extension of these physical features. However, there is a distinguishing feature of breakouts in resistivity logs, which is the lowered resolution of the image at that breakout orientation. The lower resolution at breakouts is due to the electrical pad of the logging tool being further away from the wellbore wall when the resistivity image measurements are taken. This change in color resolution may be exploited in accordance with embodiments of the disclosure to identify the orientation of breakouts. Further, in order to assess the extent of the enlargement, provided multi-arm caliper readings are used to correlate the radial extent at every location in the wellbore. A method that relies on these characteristics is subsequently described.

FIG. 5B 1 shows a method (510) for predicting a borehole geometry based on a resistivity image log, in accordance with embodiments of the disclosure.

In the method (510), pixel RGB readings are converted to borehole radii. Similar to the previously described ultrasonic log algorithm, the method (510) relies on some data other than the image log itself to perform the interpretations process. These data include the bit size, multi-arm mechanical caliper log measurements, and a definition of the direction of the maximum in-situ stress.

Referring to the flowchart of FIG. 5B1, in Step 512, a physical dimension is assigned to the pixels of the resistivity image log. The physical dimensions may include a depth and a circumferential angle. The bit size, e.g., the radius of the drill bit, may be used to determine the circumferential angle.

In Step 514, the minimum and maximum caliper measurements (CALₘᵢₙ, CALₘₐₓ) are obtained.

In Step 516, the maximum in-situ stress direction is determined using the wellbore breakout azimuth (indicating the direction of the minimum in-situ stress), obtained from the ultrasonic image log. The maximum in-situ stress direction is employed to correlate with the direction of wellbore enlargements or breakouts as observed in the resistivity image log.

In Step 518, the circumferential angle ranges with lowered image resolution (θc1, θc2, θc3, θc4) are determined, where 1 and 2 define the starting and final angle of the first zone while 3 and 4 define the rage for the second zone.

The subsequently described operations may be performed to process for each pixel in a horizontal line and for each recorded depth, the RGB reading of the pixel. Accordingly, at least some of the steps may be repeatedly performed in a loop, e.g., as shown in the implementation of FIG. 5B2. In these operations, the resistivity image log is adjusted using values obtained from the mechanical caliper log.

In Step 520, the image gaps in the resistivity image log are processed. The resulting RGB_{adj} is the adjusted RGB reading for filtering out noise and image gaps in the image. The adjustment process relies of an upper cutoff value of 0 for each pixel green color value (G_{cutoff}), a lower value of 50 for each pixel red color value (R_{cutoff}), a lower value of 0 for the subtraction of blue from red color values (R-B_{cutoff}). An example of how the adjustment may be performed is illustrated in the implementation example of FIG. 5B2.

In Step 522, a feature scaling is performed to determine the radius. As further illustrated in FIG. 5B2, the features scaling may be performed in a series of steps as subsequently described.

First, a feature-scaled radius may be determined. The feature scaled radius may be determined for red and blue pixel values. The following operations may be used:

$$\\ {r}_{FSRed} = {CAL}_{min} + ( \frac{{Red}_{adj} - {Red}_{adj - min}}{{Red}_{adj - max} - {Red}_{adj - min}} ( {CAL}_{max} - {CAL}_{min} ) )$$

$$\\ {r}_{FSBlue} = {CAL}_{min} + ( \frac{{Blue}_{adj} - {Blue}_{adj - min}}{{Blue}_{adj - max} - {Blue}_{adj - min}} ( {CAL}_{max} - {CAL}_{min} ) )$$

Next, the feature-scaled radius, may be adjusted depending on whether it is in the low-resolution region. If r_{FSRed} within the low resolution angles (θc1, θc2, θc3, θc4) is less than CALₘₐₓ, then r_{FSRed} is increased by an increment that is determined as follows:

$$\\ {r}_{FSRed} Increment = {CAL}_{max} - {r}_{FSRed}$$

Similarly, for r_{FSBlue}, if r_{FSBlue} within the low resolution angles (θc1, θc2, θc3, θc4) is less than CALₘₐₓ, then r_{FSRed} is increased by an increment that is determined as follows:

$$\\ {r}_{FSBlue} Increment = {CAL}_{max} - {r}_{FSBlue}$$

Based on the increments, updated radial measurements are calculated. The updated radial measurements may be calculated for both red and blue both on the increments previously calculated as follows: (these calculations are only made for the angles within the low resolution range (θc1, θc2, θc3, θc4))

$$\\ {( {r}_{FSRed} )}_{LS} = {r}_{FSRed} + {r}_{FSRed} Increment$$

$$\\ {( {r}_{FSBlue} )}_{LS} = {r}_{FSBlue} + {r}_{FSBlue} Increment$$

Finally, a feature scaling is performed to both of the incremented low-resolution red and blue radii ((r_{FSRed})_{LS}, (r_{FSBlue})_{LS}) as follows:

$$\\ {( {r}_{FSRed} )}_{LS - FS} = {CAL}_{min} + ( \frac{{( {r}_{FSRed} )}_{LS} - {( {r}_{FSRed} )}_{LS - min}}{{( {r}_{FSRed} )}_{LS - max} - {( {r}_{FSRed} )}_{LS - min}} ( {CAL}_{max} - {CAL}_{min} ) )$$

$$\\ {( {r}_{FSBlue} )}_{LS - FS} = {CAL}_{min} + ( \frac{{( {r}_{FSBlue} )}_{LS} - {( {r}_{FSBlue} )}_{LS - min}}{{( {r}_{FSBlue} )}_{LS - max} - {( {r}_{FSBlue} )}_{LS - min}} ( {CAL}_{max} - {CAL}_{min} ) )$$

where CALₘᵢₙ and CALₘₐₓ are minimum and maximum multi-arm mechanical caliper radius readings respectively, which are used for calibration. The resulting values for red and blue may be averaged.

Using this method for interpreting image logs means that the availability of multi-arm caliper data is a necessity when resistivity images are used. Accordingly, the method may not be executed in real-time. This is to be expected since conventional resistivity-based image logs are not available through LWD in the same manner as density-based images.

FIG. 5B2 shows an implementation example of a method for estimating a borehole geometry based on a resistivity image log, in accordance with embodiments of the disclosure. In the implementation example (520), individual operations, corresponding to the steps of the method (510), are shown. Other implementations may be used, without departing from the disclosure.

FIG. 5C shows an example of a comparison of a resistivity image log and the corresponding RGB numbers (530), in accordance with embodiments of the disclosure. The upper panel of FIG. 5C shows a clear correlation between the location of the image gaps, the low-resolution areas, and the trends in the RGB numbers. The lower panel of FIG. 5C shows the adjusted RGB numbers of the resistivity image log. The adjusted RGB values account for the image gaps and other image noise.

FIG. 5D shows an example of a resistivity log interpretation (540), in accordance with embodiments of the disclosure. The left panel of FIG. 5D provides the results of the resistivity image log interpretation showing radial measurements in cartesian coordinates. The right panel of FIG. 5D provides the results of the resistivity image log interpretation showing radial measurements in polar coordinates to reflect the actual shape of the wellbore cross-section.

These final results of the image log interpretations are calibrated with mechanical caliper log readings and are shown in both cartesian and polar coordinates. Comparison of the resistivity image log interval of FIG. 5A to the interpreted radial measurements of FIG. 5D, clearly shows that the low-resolution regions in the image that signify the presence of wellbore enlargements are also reflected as radial measurements that are higher than the bit radius. Also, when examining the highlighted mechanical caliper readings (identified by the rectangle in the left panel of FIG. 5A, it can be clearly seen that there is an agreement that the wellbore is fully enlarged at all directions.

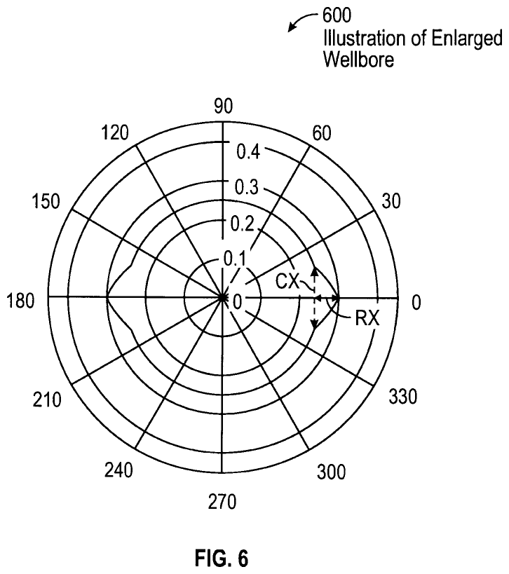

FIG. 6 shows an illustration of an enlarged wellbore (600), in accordance with embodiments of the disclosure. Conventionally, the circumferential extension, CX, is identified. However, using the methods described in reference to FIGS. 4A-4E and 5A-5D, the radial extension, RX, maybe obtained, in addition. In the subsequently discussed methods for determining the parameters of mechanical earth models, the availability of RX may help constrain the value of the maximum in-situ stress more accurately.

The subsequently discussed figures relate to estimating parameters of a mechanical earth model (MEM) using a stress regime polygon-based approach, and further the use of finite element methods based on the obtained MEM parameters. In one or more embodiments, a three-dimensional poro-elasto-plastic finite element model for solids and geomechanics is generated. The model code includes a pre-processing procedure for the purpose of assigning loads, creating the initial mesh, and assigning heterogenous material properties.

FIG. 7A shows the use of a stress regime polygon (700) to obtain mechanical earth model parameters. Importantly, applying the stress regime polygon to the output of the methods as described yields better results than what would be achievable using manual interpretation of the images.

FIG. 7B shows an illustration of a pre-processing for a finite element model (FEM) simulation (710) based on the obtained MEM parameters, in accordance with embodiments of the disclosure. The pre-processing procedure as described assigns loads, creates an initial mesh, and assigns heterogenous material properties. The output of the pre-processing procedure may serve as input to the FEM simulation. A file may be used to hand over the output of the pre-processing procedure to the FEM simulation.

FIG. 7C shows an example of an FEM simulation (720), in accordance with embodiments of the disclosure. After the preprocessing as described in reference to FIG. 7B, the output of the pre-processing may be ingested by the FEM simulation (710). While FIG. 7B shows a particular FEM simulation, other FEM simulations may be used, without departing from the disclosure.

The output file from the pre-processing code (e.g., FIG. 7B) is inserted as an input into the core finite element code (e.g., FIG. 7C).

The model applies discretization using the minimization of the total potential energy, which produces the following equilibrium:

$$\\ u {\int }_{{V}^{{}_{} e}} ( ( {B}^{{}_{} T} ) DB ) d Ω = {\int }_{{V}^{{}_{} e}} {N}^{{}_{} T} Fd Ω - {\int }_{{S}^{{}_{} e}} {N}^{{}_{} T} Td Γ ,$$

where u is the displacement, B and B^{T} are the strain-displacement matrix and its transpose, respectively. N^{T} is the transpose of the quadratic Serendipity shape functions vector, which are derived for a 20-nodes isoparametric brick element that is depicted in FIG. 7B, D is the consistent tangent matrix, which is formulated based on mechanical properties of the rock, F is the body force, and T is the traction force. The body and traction forces reflect the in-situ stresses and mud weight loading on the wellbore. The integrations in this equation are performed at the element volume (V^{e}) with respect to the volume variable (Ω) or at the element surface (S^{e}) with respect to the area variable (Γ). The matrix resulting from the integral in the expression to the left is known as the stiffness matrix (K^{e}).

The finite element model relies on the plastic flow rule for strain hardening to reflect the plastic behavior of the rock, which occurs beyond the yield point. This means that the total strain is the addition of two components, which are poro-elastic strain (ε^{e}) and a plastic strain (ε^{P}). The plastic flow rule assumes that the flow direction is perpendicular to the yield surface ψ and it is defined as:

$$\\ Δ {ε}_{ij}^{{}_{} p} = λ \frac{\partial ψ ( {σ}_{ij} )}{\partial {σ}_{ij}} ,$$

where εᵢⱼ^{p} is the plastic strain tensor, σᵢⱼ is the stress tensor, and λ is the plastic strain multiplier. The associative flow rule is applied by assuming that the plastic potential surface is the same as the yield surface ψ. It also assumes the yield surface expands without changing the flow direction. The yield criterion used in this work is the Drucker-Prager criterion, where yielding will take place when the deviatoric stress tensor (Sᵢⱼ) and the mean stress (σₘ) satisfy the following relationship:

$$\\ ψ ( {σ}_{ij} ) = \sqrt{\frac{1}{2} {S}_{ij} {S}_{ij}} - {a}_{0} + {a}_{1} {σ}_{m} = 0$$

where constants a₀ and a₁ are determined experimentally as material properties and are used to correlate the Drucker-Prager criterion to the Mohr-Coulomb criterion.

The following expression for strain hardening is then used to calculate the scalar plastic strain EP from the plastic strain tensor determined by the flow rule:

$$\\ {ε}^{{}_{} p} = \int \sqrt{\frac{2}{3} d {ε}_{ij}^{{}_{} p} d {ε}_{ij}^{{}_{} p}}$$

The FEM, in the example is implemented through 33 subroutines and a driver code. The driver code calls twelve main subroutines, and these perform several functions including receiving the input file, applying loads to construct and assemble the global stiffness matrix, and solving the system of equations. Upon solving the system of equations and determining the displacements u, the residual forces are calculated to check for convergence and equilibrium by subtracting the left-hand side from the right-hand side in the global form, where the left-hand side is the global stiffness matrix multiplied by displacement and the right-hand side is the body and traction forces. The value obtained from the subtraction of these two quantities should be equal to zero if the equilibrium condition is fully satisfied. However, because this is not always achievable, a tolerance value is set to check for convergence. The tolerance value may be set close to but not equal to zero. Once the residual forces are calculated and found to be less than the set tolerance value, convergence is said to be achieved, otherwise, the residual forces are carried to the next iteration. The same process is repeated for each separate load increment, where the load increments are defined in the input file manually. These processes are carried out in two loops with the convergence loop nested in the load increment loop as shown in FIG. 7C.

One significant benefit of using the FEM simulation as shown is that it is not limited to linear elastic models based on analytical solutions or simplified numerical solutions as commonly used in drilling engineering. Further, the proposed model is computationally efficient, which allows for a real-time or a while-drilling implementation of the model. This setup of the finite element model may be used to decide several parameters relating to wellbore rock failure, chief among these is the mud weight or downhole pressure required for preventing wellbore failure. An example of the initial output of the model, which relates to recommending mud weights for preventing wellbore rock failure is shown in FIG. 7D.

FIG. 7D shows example recommendations of muds weights and downhole pressures for a drilling operation, in accordance with embodiments of the disclosure. These data were obtained using the previously described MEM parameters and/or the FEM simulation and reflect mud weights/downhole pressures that prevent wellbore rock failure, based on the simulation results. Two different examples are shown.

Embodiments may be implemented on a computer system. FIG. 8 is a block diagram of a computer system (802) used to provide computational functionalities associated with described algorithms, methods, functions, processes, flows, and procedures as described in the instant disclosure, according to an implementation. The illustrated computer (802) is intended to encompass any computing device such as a high performance computing (HPC) device, a server, desktop computer, laptop/notebook computer, wireless data port, smart phone, personal data assistant (PDA), tablet computing device, one or more processors within these devices, or any other suitable processing device, including both physical or virtual instances (or both) of the computing device. Additionally, the computer (802) may include a computer that includes an input device, such as a keypad, keyboard, touch screen, or other device that can accept user information, and an output device that conveys information associated with the operation of the computer (802), including digital data, visual, or audio information (or a combination of information), or a GUI.

The computer (802) can serve in a role as a client, network component, a server, a database or other persistency, or any other component (or a combination of roles) of a computer system for performing the subject matter described in the instant disclosure. The illustrated computer (802) is communicably coupled with a network (830). In some implementations, one or more components of the computer (802) may be configured to operate within environments, including cloud-computing-based, local, global, or other environment (or a combination of environments).

At a high level, the computer (802) is an electronic computing device operable to receive, transmit, process, store, or manage data and information associated with the described subject matter. According to some implementations, the computer (802) may also include or be communicably coupled with an application server, e-mail server, web server, caching server, streaming data server, business intelligence (BI) server, or other server (or a combination of servers).

The computer (802) can receive requests over network (830) from a client application (for example, executing on another computer (802)) and responding to the received requests by processing the said requests in an appropriate software application. In addition, requests may also be sent to the computer (802) from internal users (for example, from a command console or by other appropriate access method), external or third-parties, other automated applications, as well as any other appropriate entities, individuals, systems, or computers.

Each of the components of the computer (802) can communicate using a system bus (803). In some implementations, any or all of the components of the computer (802), both hardware or software (or a combination of hardware and software), may interface with each other or the interface (804) (or a combination of both) over the system bus (803) using an application programming interface (API) (812) or a service layer (813) (or a combination of the API (812) and service layer (813). The API (812) may include specifications for routines, data structures, and object classes. The API (812) may be either computer-language independent or dependent and refer to a complete interface, a single function, or even a set of APIs. The service layer (813) provides software services to the computer (802) or other components (whether or not illustrated) that are communicably coupled to the computer (802). The functionality of the computer (802) may be accessible for all service consumers using this service layer. Software services, such as those provided by the service layer (813), provide reusable, defined business functionalities through a defined interface. For example, the interface may be software written in JAVA, C++, or other suitable language providing data in extensible markup language (XML) format or other suitable format. While illustrated as an integrated component of the computer (802), alternative implementations may illustrate the API (812) or the service layer (813) as stand-alone components in relation to other components of the computer (802) or other components (whether or not illustrated) that are communicably coupled to the computer (802). Moreover, any or all parts of the API (812) or the service layer (813) may be implemented as child or sub-modules of another software module, enterprise application, or hardware module without departing from the scope of this disclosure.

The computer (802) includes an interface (804). Although illustrated as a single interface (804) in FIG. 8, two or more interfaces (804) may be used according to particular needs, desires, or particular implementations of the computer (802). The interface (804) is used by the computer (802) for communicating with other systems in a distributed environment that are connected to the network (830). Generally, the interface (804 includes logic encoded in software or hardware (or a combination of software and hardware) and operable to communicate with the network (830). More specifically, the interface (804) may include software supporting one or more communication protocols associated with communications such that the network (830) or interface's hardware is operable to communicate physical signals within and outside of the illustrated computer (802).

The computer (802) includes at least one computer processor (805). Although illustrated as a single computer processor (805) in FIG. 8, two or more processors may be used according to particular needs, desires, or particular implementations of the computer (802). Generally, the computer processor (805) executes instructions and manipulates data to perform the operations of the computer (802) and any algorithms, methods, functions, processes, flows, and procedures as described in the instant disclosure.

The computer (802) also includes a memory (806) that holds data for the computer (802) or other components (or a combination of both) that can be connected to the network (830). For example, memory (806) can be a database storing data consistent with this disclosure. Although illustrated as a single memory (806) in FIG. 8, two or more memories may be used according to particular needs, desires, or particular implementations of the computer (802) and the described functionality. While memory (806) is illustrated as an integral component of the computer (802), in alternative implementations, memory (806) can be external to the computer (802).

The application (807) is an algorithmic software engine providing functionality according to particular needs, desires, or particular implementations of the computer (802), particularly with respect to functionality described in this disclosure. For example, application (807) can serve as one or more components, modules, applications, etc. Further, although illustrated as a single application (807), the application (707) may be implemented as multiple applications (807) on the computer (702). In addition, although illustrated as integral to the computer (802), in alternative implementations, the application (807) can be external to the computer (802).

There may be any number of computers (802) associated with, or external to, a computer system containing computer (802), each computer (802) communicating over network (830). Further, the term “client,” “user,” and other appropriate terminology may be used interchangeably as appropriate without departing from the scope of this disclosure. Moreover, this disclosure contemplates that many users may use one computer (802), or that one user may use multiple computers (802).

In some embodiments, the computer (802) is implemented as part of a cloud computing system. For example, a cloud computing system may include one or more remote servers along with various other cloud components, such as cloud storage units and edge servers. In particular, a cloud computing system may perform one or more computing operations without direct active management by a user device or local computer system. As such, a cloud computing system may have different functions distributed over multiple locations from a central server, which may be performed using one or more Internet connections. More specifically, cloud computing system may operate according to one or more service models, such as infrastructure as a service (IaaS), platform as a service (PaaS), software as a service (SaaS), mobile “backend” as a service (MBaaS), serverless computing, artificial intelligence (AI) as a service (AlaaS), and/or function as a service (FaaS).

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims.

What is claimed:

1. A method for obtaining mechanical earth model (MEM) parameters, the method comprising:
obtaining an ultrasonic image log for a borehole;
based on the ultrasonic image log, obtaining an estimate of a borehole geometry for an entire circumference of the borehole in an interval of the ultrasonic image log; and
estimating the MEM parameters using the estimate of the borehole geometry.

2. The method of claim 1, further comprising determining a mud weight for a drilling operation, using the MEM parameters.

3. The method of claim 1, wherein the ultrasonic image log is obtained using a logging while drilling tool.

4. The method of claim 1, wherein obtaining the estimate of the borehole geometry comprises converting red-green-blue (RGB) values of pixels in the ultrasonic image log to radial measurements.

5. The method of claim 4, wherein the converting of the RGB values of the pixels to the radial measurement uses a calibration specific to a logging tool.

6. The method of claim 1, wherein the borehole geometry comprises an identification of a circumferential extension and a radial extension.

7. The method of claim 1, wherein estimating the MEM parameters comprises analyzing a stress regime polygon using the borehole geometry.

8. The method of claim 7, wherein the analyzing of the stress regime polygon provides an in-situ maximum horizontal stress.

9. The method of claim 1, further comprising generating a 3D finite element drilling geomechanics model using the borehole geometry.

10. The method of claim 9, wherein the 3D finite element drilling geomechanics model considers plastic behavior of rock.

11. The method of claim 1, wherein the MEM parameters are obtained in real-time while drilling.

12. A method for obtaining mechanical earth model (MEM) parameters, the method comprising:
obtaining a resistivity image log and a mechanical caliper log for a borehole;
based on the resistivity image log, adjusted using values from the mechanical caliper log, obtaining an estimate of a borehole geometry for an entire circumference of the borehole in an interval of the resistivity image log; and
estimating the MEM parameters using the estimate of the borehole geometry.

13. The method of claim 12, further comprising determining a mud weight for a drilling operation, using the MEM parameters.

14. The method of claim 12, wherein obtaining the estimate of the borehole geometry comprises converting red-green-blue (RGB) values of pixels in the resistivity image log to radial measurements.

15. The method of claim 14, wherein the converting of the RGB values of the pixels to the radial measurement comprises determining, in the resistivity image log, circumferential angle ranges with lowered image resolution that signify a presence of wellbore enlargements.

16. The method of claim 15, wherein the converting of the RGB values of the pixels to the radial measurement further comprises processing image gaps in the resistivity image log, wherein the image gaps are due to spaces between electrical pads of a resistivity image logging tool used for obtaining the resistivity image log.

17. The method of claim 15, wherein the converting of the RGB values of the pixels to the radial measurement further comprises, in the circumferential angle ranges with lowered image resolution, incrementing a radius obtained from the resistivity image log, using the values from the mechanical caliper log.

18. The method of claim 12, wherein the borehole geometry comprises an identification of a circumferential extension and a radial extension.

19. The method of claim 12, wherein estimating the MEM parameters comprises analyzing a stress regime polygon using the borehole geometry.

20. A system for obtaining mechanical earth model (MEM) parameters, the system comprising:
an ultrasound image log interpretation engine executing on at least one processor and configured to:
obtain an ultrasonic image log for a borehole; and
a mechanical earth model simulation engine executing on the at least one processor and configured to:
based on the ultrasonic image log, obtain an estimate of a borehole geometry for an entire circumference of the borehole in an interval of the ultrasonic image log, and
estimate the MEM parameters using the estimate of the borehole geometry.
